(19) United States
(12) Patent Application Publication
(10) Pub. No.: US 2017/0345873 A1
(43) Pub. Date: Nov. 30, 2017

(54) DRIVING CIRCUIT AND OPERATING METHOD THEREOF

(71) Applicant: Raydium Semiconductor Corporation, Hsinchu (TW)

(72) Inventor: Hung Li, Taipei City (TW)

(21) Appl. No.: 15/590,255

(22) Filed: May 9, 2017

Related U.S. Application Data
(60) Provisional application No. 62/342,227, filed on May 27, 2016.

(51) Int. Cl. H01L 27/32; G06F 3/14; G09G 3/3208; H05B 33/08; G06T 1/60; H01L 51/56; G06F 3/147

(52) U.S. Cl. CPC H01L 27/32; G09G 3/3208; G06F 3/1415; G06F 3/147; G06T 1/60; H01L 51/56; H05B 33/0896

(57) ABSTRACT

A driving circuit and an operating method thereof are disclosed. The driving circuit is disposed in a display apparatus and coupled to an OLED display panel. The driving circuit includes a buffer module, a regenerating module, a data processing module and a driving module. The buffer module receives and temporarily stores a first image data. The regenerating module generates a second image data different from the first image data according to the first image data. The data processing module performs a data processing process on the second image data to generate an output image data. The driving module is coupled between the data processing module and the OLED display panel and used to output an output the output image data to the OLED display panel.

### BACKGROUND OF THE INVENTION

### 1. Field of the Invention

This invention relates to a display, especially to a driving circuit of a display apparatus having an organic light-emitting diode (OLED) display panel and an operating method thereof.

### 2. Description of the Prior Art

In a conventional display apparatus having an OLED panel, the driving IC is usually used to receive image data inputted from outside and the digital image processing circuit is used to perform data process on the image data; and then, the processed image data is transmitted to the source driver and the source driver generates output voltage to the OLED panel.

In general, the driving IC usually has a memory to store the image data inputted from outside; for example, the driving circuit in FIG. 1 includes a buffer module 13 which can have a structure of frame buffer or line buffer. When the image data is not inputted from outside, the image data previously stored in the buffer module 13 can be transmitted to the OLED panel PL to display, so that the OLED panel PL can continuously display image without stopping.

Although the OLED panel PL will not stop displaying image due to no data inputted from outside, the OLED panel PL only statically display the image data previously stored in the buffer module 13 without any changes. In addition, as to the OLED panel PL, if the OLED panel PL continuously displays the same still image for a long period of time, the OLED panel PL will appear branded and its service life will be significantly reduced. The above-mentioned drawbacks in the prior arts should be overcome.

### SUMMARY OF THE INVENTION

Therefore, the invention provides a driving circuit of a display apparatus having an organic light-emitting diode (OLED) display panel and an operating method thereof to solve the above-mentioned problems in the prior arts.

An embodiment of the invention is a driving circuit. In this embodiment, the driving circuit is disposed in a display apparatus and coupled to a display panel. The driving circuit includes a buffer module, a regenerating module, a data processing module and a driving module. The buffer module is used for receiving and temporarily storing a first image data. The regenerating module is coupled to the buffer module and used for generating a second image data different from the first image data according to the first image data. The data processing module is coupled to the regenerating module and used for performing a data processing process on the second image data to generate an output image data. The driving module is coupled between the data processing module and the display panel and used for outputting the output image data to the display panel.

In an embodiment, the display panel is an organic light-emitting diode (OLED) display panel.

In an embodiment, the driving circuit further includes a transmission interface and another data processing module. The transmission interface is used for receiving an input image data from outside. The another data processing module is coupled between the transmission interface and the buffer module and used for performing a data processing process on the input image data to generate the first image data to the buffer module.

In an embodiment, the regenerating module includes a control unit and a regenerating unit. The control unit is used for generating a control signal according to an image position information of the first image data and a display position information of the display panel. The regenerating unit is coupled to the control unit and the data processing module respectively and used for generating the second image data to the data processing module according to the control signal and the first image data.

In an embodiment, the regenerating unit further receives an original image data and generates the second image data to the data processing module according to the control signal, the first image data and the original image data.

In an embodiment, the image position information of the first image data includes a current position information, a target position information and a boundary information of the first image data.

In an embodiment, the regenerating module further includes a position information processing unit coupled to the control unit and used for generating the image position information of the first image data to the control unit according to a size information and a start display position information of the first image data.

In an embodiment, the regenerating module uses the first image data to perform a dynamic display process on the original image data according to the control signal to obtain the second image data.

In an embodiment, the dynamic display process is to dynamically superimposing the first image data on the original image data, the first image data is displayed on a start position and the first image data is displayed on at least one motion trajectory coordinate in order or randomly after a period of time, and the at least one motion trajectory coordinate is a preset coordinate or a randomly generated coordinate.

In an embodiment, the first image data is only displayed on the start position and the at least one motion trajectory coordinate, or the first image data is displayed between the start position and the at least one motion trajectory coordinate in a gradually progressive way.

In an embodiment, after the first image data is displayed on the at least one motion trajectory coordinate, the first image data comes back to the start position and starts to be displayed cyclically.

Another embodiment of the invention is a driving circuit operating method. In this embodiment, the driving circuit operating method is used for operating a driving circuit disposed in a display apparatus. The driving circuit is coupled to a display panel. The driving circuit includes a buffet module, a regenerating module, a data processing module and a driving module. The regenerating module is coupled between the buffer module and the data processing module. The driving module is coupled between the data processing module and the display panel. The driving circuit operating method includes steps of: the buffer module receiving and temporarily storing a first image data; the regenerating module generating a second image data different from the first image data according to the first image data; the data processing module performing a data processing process on the second image data to generate an output image data; and the driving module outputting the output image data to the display panel.

Compared to the prior art, the driving circuit and operating method thereof in the invention can provide the following advantages and effects:

No matter the image data displayed by the OLED display panel is a still image or not, another image data having an appropriate size can be provided from outside and stored in the memory of the driving circuit, and the another image data can be dynamically superimposed on the image data displayed by the OLED display panel, so that the superimposed image displayed by the OLED display panel can have local dynamical changes to increase the changing effect of the displayed image and effectively avoid the OLED panel PL appearing branded; therefore, the service life of the OLED display panel can be significantly increased.

The advantage and spirit of the invention may be understood by the following detailed descriptions together with the appended drawings.

### BRIEF DESCRIPTION OF THE APPENDED DRAWINGS

FIG. 1 illustrates a schematic diagram of the driving circuit in the prior art.

FIG. 2 illustrates a functional block diagram of the driving circuit in an embodiment of the invention.

FIG. 3 illustrates a detailed functional block diagram of the regenerating module in FIG. 2.

FIG. 4A-4C illustrate schematic diagrams of the OLED display panel, the original image data and the first image data respectively.

FIG. 5 illustrates a schematic diagram of the second image data obtained after the first image data shown in FIG. 4C is used to perform dynamic displaying process on the original image data shown in FIG. 4B.

FIG. 6A-6C illustrate the second image data displayed at the first position the third position at the first time˜the third time in order respectively.

FIG. 7 illustrates the flowchart of the driving circuit operating method in another embodiment of the invention.

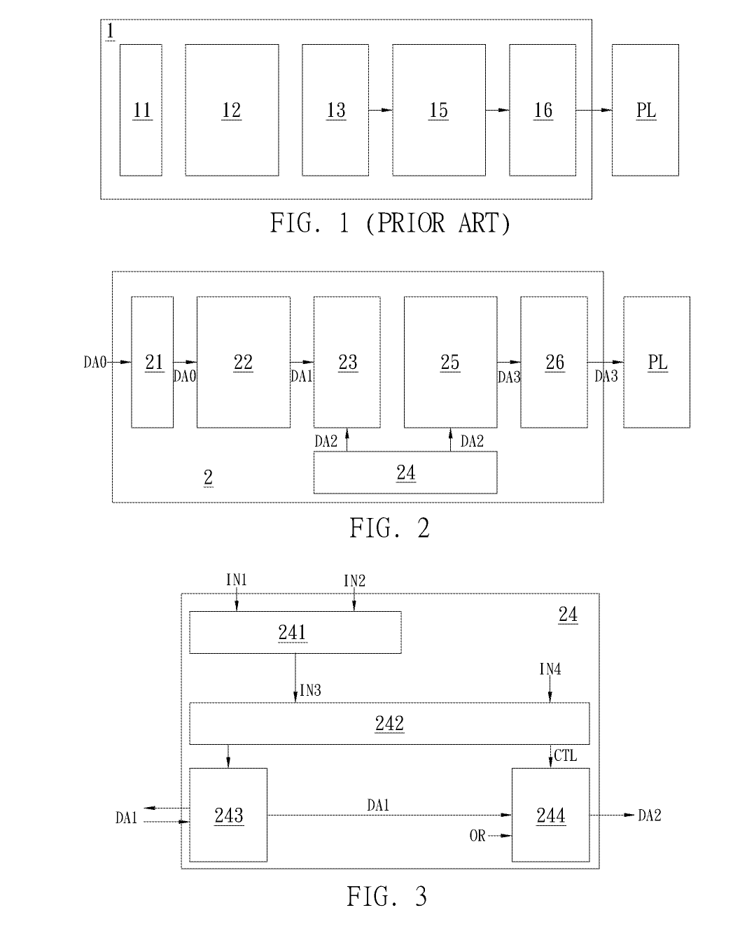

### DETAILED DESCRIPTION OF THE INVENTION

A preferred embodiment of the invention is a driving circuit. In this embodiment, the driving circuit is disposed in a display apparatus and coupled to an OLED display panel, but not limited to this.

Please refer to FIG. 2. FIG. 2 illustrates a functional block diagram of the driving circuit in this embodiment. As shown in FIG. 2, the driving circuit 2 is coupled to the OLED display panel PL. The driving circuit 2 includes a transmission interface 21, a first data processing module 22, a buffer module 23, a regenerating module 24, a second data processing module 25 and a driving module 26. Wherein, the first data processing module 22 is coupled between the transmission interface 21 and the buffer module 23; the regenerating module 24 is coupled between the buffer module 23 and the second data processing module 25; the driving module 26 is coupled between the second data processing module 25 and the OLED display panel PL.

In this embodiment, the buffer module 23 is used to receive and temporarily storing a first image data DA1. It should be noticed that the first image data DA1 can be generated after the transmission interface 21 receives an input image data DA0 from outside and the first data processing module 22 performs a data processing process on the input image data DA0 and the first image data DA1 can be temporarily stored in the buffer module 23; or the first image data DA1 can be a system default image data and stored in the buffer module 23. The regenerating module 24 is used for generating a second image data DA2 different from the first image data DA1 according to the first image data DA1. The second data processing module 25 is used for performing a data processing process on the second image data DA2 to generate an output image data DA3. The driving module 26 is used for outputting the output image data DA3 to the OLED display panel PL.

Then, please refer to FIG. 3. FIG. 3 illustrates a detailed functional block diagram of the regenerating module 24 in FIG. 2. As sown in FIG. 3, the regenerating module 24 includes a position information processing unit 241, a control unit 242, a buffer control unit 243 and a regenerating unit 244; the buffer control unit 243 is coupled to the regenerating unit 244.

In this embodiment, the position information processing unit 241 is used for generating the image position information IN3 of the first image data DA1 to the control unit 242 according to a size information IN1 and a start display position information IN2 of the first image data DA1. In fact, the image position information IN3 of the first image data DA1 can include a current position information, a target position information and a boundary information of the first image data DA1, but not limited to this.

The control unit 242 not only receives the image position information IN3 of the first image data DA1 from the position information processing unit 241, but also receives a display position information IN4 of the OLED display panel PL. Thus, the control unit 242 can generate a control signal CTL according to the image position information IN3 of the first image data DA1 and the display position information IN4 of the OLED display panel PL.

The regenerating unit 244 not only receives the control signal CTL transmitted by the control unit 242, but also receives the first image data DA1 from the buffer control unit 243 and an original image data OR. Thus, the regenerating unit 244 can generate the second image data DA2 to the second data processing module 25 according to the control signal CTL, the first image data DA1 and the original image data OR.

It should be noticed that the regenerating unit 244 can use the first image data DA1 to perform a dynamic display process on the original image data OR according to the control signal CTL to obtain the second image data DA2. For example, the regenerating unit 244 can dynamically superimpose the first image data DA1 on the original image data OR to form the second image data DA2, but not limited to this.

In practical applications, when the regenerating unit 244 dynamically superimposes the first image data DA1 on the original image data OR, the first image data DA1 can be displayed on a start position and then displayed on at least one motion trajectory coordinate in order or randomly after a period of time. The at least one motion trajectory coordinate can be a preset coordinate or a randomly generated coordinate.

Then, the following embodiments will be used to introduce the invention in detail.

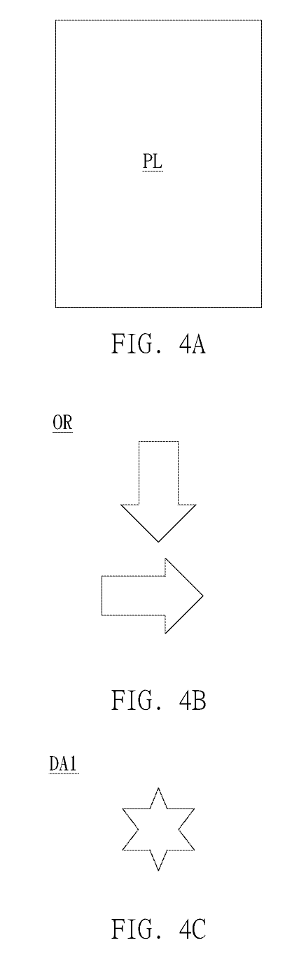

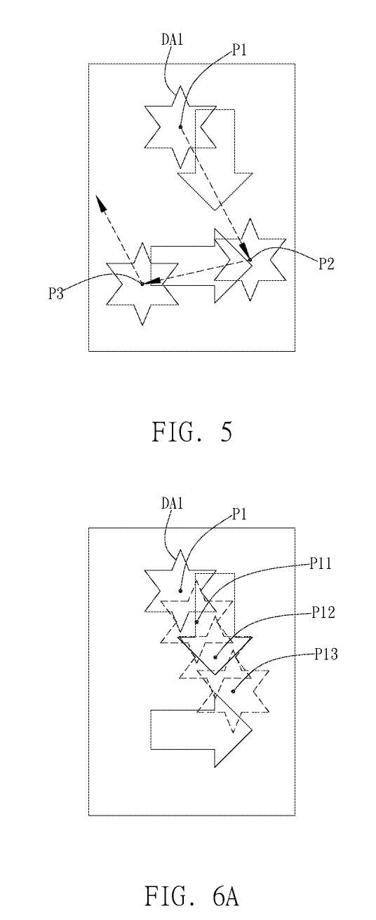

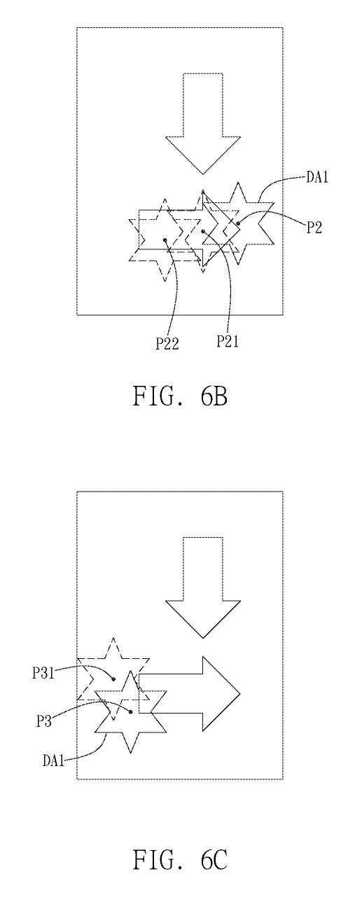

Please refer to FIG. 4A˜FIG. 4C. FIG. 4A˜4C illustrate schematic diagrams of the OLED display panel PL, the original image data OR and the first image data DA1 respectively. Then, please also refer to FIG. 5 and FIG. 6A˜FIG. 6C. FIG. 5 illustrates a schematic diagram of the second image data DA2 obtained after the first image data DA1 shown in FIG. 4C is used to perform the dynamic displaying process on the original image data OR shown in FIG. 4B; FIG. 6A˜FIG. 6C illustrate the second image data DA2 displayed at the first position P1˜the third position P3 at the first time˜the third time in order respectively.

As shown in FIG. 5, the regenerating unit 244 uses the first image data DA1 shown in FIG. 4C to perform the dynamic display process on the original image data OR shown in FIG. 4B according to the control signal CTL to obtain the second image data DA2. For example, the regenerating unit 244 can dynamically superimpose the first image data DA1 on the original image data OR according to the control signal CTL to form the second image data DA2, but not limited to this.

In detail, when the regenerating unit 244 dynamically superimposes the first image data DA1 on the original image data OR according to the control signal CTL, the regenerating unit 244 can display the first image data DA1 on a start position (e.g., the first position P1) and then the first image data DA1 can be displayed on at least one motion trajectory coordinate (e.g., the second position P2˜the third position P3) in order or randomly after a period of time. In fact, the at least one motion trajectory coordinate can be a preset coordinate or a randomly generated coordinate without specific limitations.

It should be noticed that when the regenerating unit 244 dynamically superimposes the first image data DA1 on the original image data OR according to the control signal CTL, the first image data DA1 can be only displayed on the start position (e.g., the first position P1) and the at least one motion trajectory coordinate (e.g., the second position P2˜the third position P3), or the first image data DA1 can be displayed between the start position and the at least one motion trajectory coordinate in a gradually progressive way. As shown in FIG. 6A˜FIG. 6C, the first image data DA1 is not only displayed on the first position P1 and the second position P2, but also displayed on the display positions P11, P12 and P13 between the first position P1 and the second position P2 in the gradually progressive way; the first image data DA1 is not only displayed on the second position P2 and the third position P3, but also displayed on the display positions P21 and P22 between the second position P2 and the third position P3 in the gradually progressive way, and so on.

It should be noticed that when the first image data DA1 is displayed in the gradually progressive way, the first image data DA1 can be not only displayed on different positions, but also have other changes (e.g., rotating an angle on certain positions) to increase the visibility of the displayed image. After the first image data DA1 is displayed on the last motion trajectory coordinate, the first image data DA1 can come back to the start position (e.g., the first position P1) and start to be displayed cyclically, but not limited to this.

In addition, if the buffer module 23 stores more than one first image data DA1, the regenerating module 24 can also display a plurality of first image data DA1 in order or in turn randomly on the start position and the at least one motion trajectory coordinate to increase the visibility of the displayed image.

Above all, even the image data displayed by the OLED display panel is a still image, the driving circuit of the invention can still dynamically superimpose another image data stored in the memory of the driving circuit on the still image displayed by the OLED display panel, so that the superimposed image displayed by the OLED display panel can have local dynamical changes to increase the changing effect of the displayed image and effectively avoid the OLED panel appearing branded due to continuously displaying the same still image for a long period of time; therefore, the service life of the OLED display panel can be significantly increased.

Another embodiment of the invention is a driving circuit operating method. In this embodiment, the driving circuit operating method is used for operating a driving circuit disposed in a display apparatus. The driving circuit is coupled to a display panel. The driving circuit includes a buffet module, a regenerating module, a data processing module and a driving module. The regenerating module is coupled between the buffer module and the data processing module. The driving module is coupled between the data processing module and the display panel.

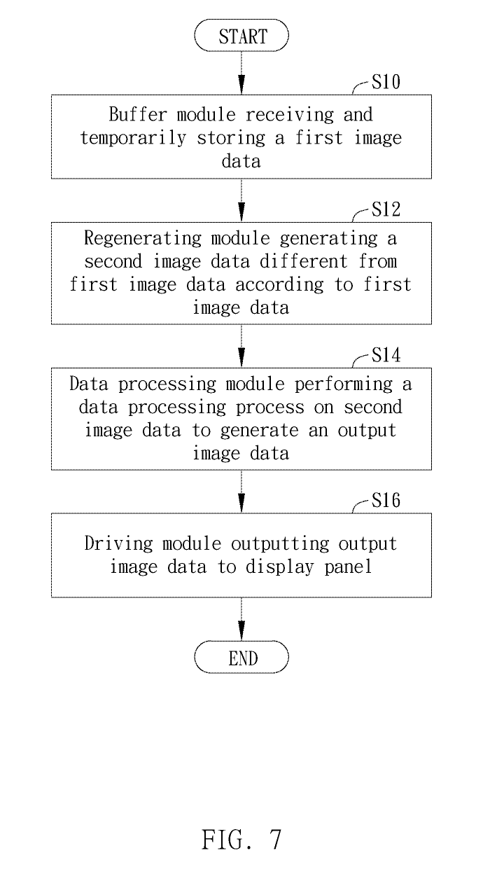

Please refer to FIG. 7. FIG. 7 illustrates the flowchart of the driving circuit operating method in this embodiment. As shown in FIG. 7, the driving circuit operating method includes the following steps of:

Step S10: the buffer module receiving and temporarily storing a first image data;

Step S12: the regenerating module generating a second image data different from the first image data according to the first image data;

Step S14: the data processing module performing a data processing process on the second image data to generate an output image data; and

Step S16: the driving module outputting the output image data to the display panel.

Compared to the prior art, the driving circuit and operating method thereof in the invention can provide the following advantages and effects:

No matter the image data displayed by the OLED display panel is a still image or not, another image data having an appropriate size can be provided from outside and stored in the memory of the driving circuit, and the another image data can be dynamically superimposed on the image data displayed by the OLED display panel, so that the superimposed image displayed by the OLED display panel can have local dynamical changes to increase the changing effect of the displayed image and effectively avoid the OLED panel PL appearing branded; therefore, the service life of the OLED display panel can be significantly increased.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A driving circuit, disposed in a display apparatus and coupled to a display panel, the driving circuit comprising:
a buffer module, for receiving and temporarily storing a first image data;
a regenerating module, coupled to the buffer module, for generating a second image data different from the first image data according to the first image data;
a data processing module, coupled to the regenerating module, for performing a data processing process on the second image data to generate an output image data; and
a driving module, coupled between the data processing module and the display panel, for outputting the output image data to the display panel.

2. The driving circuit of claim 1, wherein the display panel is an organic light-emitting diode (OLED) display panel.

3. The driving circuit of claim 1, further comprising:
a transmission interface, for receiving an input image data from outside; and
another data processing module, coupled between the transmission interface and the buffer module, for performing a data processing process on the input image data to generate the first image data to the buffer module.

4. The driving circuit of claim 1, wherein the regenerating module comprises:
a control unit, for generating a control signal according to an image position information of the first image data and a display position information of the display panel; and
a regenerating unit, coupled to the control unit and the data processing module respectively, for generating the second image data to the data processing module according to the control signal and the first image data.

5. The driving circuit of claim 4, wherein the regenerating unit further receives an original image data and generates the second image data to the data processing module according to the control signal, the first image data and the original image data.

6. The driving circuit of claim 4, wherein the image position information of the first image data comprises a current position information, a target position information and a boundary information of the first image data.

7. The driving circuit of claim 4, wherein the regenerating module further comprises:
a position information processing unit, coupled to the control unit, for generating the image position information of the first image data to the control unit according to a size information and a start display position information of the first image data.

8. The driving circuit of claim 5, wherein the regenerating module uses the first image data to perform a dynamic display process on the original image data according to the control signal to obtain the second image data.

9. The driving circuit of claim 8, wherein the dynamic display process is to dynamically superimpose the first image data on the original image data, the first image data is displayed on a start position and the first image data is displayed on at least one motion trajectory coordinate in order or randomly after a period of time, and the at least one motion trajectory coordinate is a preset coordinate or a randomly generated coordinate.

10. The driving circuit of claim 9, wherein the first image data is only displayed on the start position and the at least one motion trajectory coordinate, or the first image data is displayed between the start position and the at least one motion trajectory coordinate in a gradually progressive way.

11. The driving circuit of claim 10, wherein after the first image data is displayed on the at least one motion trajectory coordinate, the first image data comes back to the start position and starts to be displayed cyclically.

12. A driving circuit operating method, for operating a driving circuit disposed in a display apparatus, the driving circuit being coupled to a display panel, the driving circuit comprising a buffet module, a regenerating module, a data processing module and a driving module, the regenerating module being coupled between the buffer module and the data processing module, the driving module being coupled between the data processing module and the display panel, the driving circuit operating method comprising steps of:
the buffer module receiving and temporarily storing a first image data;
the regenerating module generating a second image data different from the first image data according to the first image data;
the data processing module performing a data processing process on the second image data to generate an output image data; and
the driving module outputting the output image data to the display panel.

13. The driving circuit operating method of claim 12, wherein the display panel is an organic light-emitting diode (OLED) display panel.

14. The driving circuit operating method of claim 12, wherein the driving circuit further comprises a transmission interface and another data processing module, the transmission interface receives an input image data from outside and the another data processing module performs a data processing process on the input image data to generate the first image data to the buffer module.

15. The driving circuit operating method of claim 12, wherein the regenerating module comprises a control unit and a regenerating unit, the control unit generates a control signal according to an image position information of the first image data and a display position information of the display panel, and the regenerating unit generates the second image data to the data processing module according to the control signal and the first image data.

16. The driving circuit operating method of claim 15, wherein the regenerating unit further receives an original image data and generates the second image data to the data processing module according to the control signal, the first image data and the original image data.

17. The driving circuit operating method of claim 15, wherein the image position information of the first image data comprises a current position information, a target position information and a boundary information of the first image data.

18. The driving circuit operating method of claim 15, wherein the regenerating module further comprises a position information processing unit, the position information processing unit generates the image position information of the first image data to the control unit according to a size information and a start display position information of the first image data.

19. The driving circuit operating method of claim 16, wherein the regenerating module uses the first image data to perform a dynamic display process on the original image data according to the control signal to obtain the second image data.

20. The driving circuit operating method of claim 19, wherein the dynamic display process is to dynamically superimpose the first image data on the original image data, the first image data is displayed on a start position and the first image data is displayed on at least one motion trajectory coordinate in order or randomly after a period of time, and the at least one motion trajectory coordinate is a preset coordinate or a randomly generated coordinate.

21. The driving circuit operating method of claim 20, wherein the first image data is only displayed on the start position and the at least one motion trajectory coordinate, or the first image data is displayed between the start position and the at least one motion trajectory coordinate in a gradually progressive way.

22. The driving circuit operating method of claim 21, wherein after the first image data is displayed on the at least one motion trajectory coordinate, the first image data comes back to the start position and starts to be displayed cyclically.
